(19) United States
(12) Patent Application Publication
(10) Pub. No.: US 2020/0118828 A1
(43) Pub. Date: Apr. 16, 2020

(54) PLANARIZATION DEPTH TRIGGERED BY PROCESS INTERACTION

(71) Applicant: INTERNATIONAL BUSINESS MACHINES CORPORATION, Armonk, NY (US)

(72) Inventor: Romain Lallement, Troy, NY (US)

(21) Appl. No.: 16/157,208

(22) Filed: Oct. 11, 2018

(51) Int. Cl. H01L 21/3105; H01L 21/02

(52) U.S. Cl. CPC H01L 21/31058; H01L 21/02252; H01L 21/02247

(57) ABSTRACT

A planarization method for maintaining a substantially planar surface is presented. The method includes forming an organic planarization layer (OPL) over active devices, incorporating a dissolving factor to a predetermined depth within the OPL, and triggering the dissolving factor with an enabler to reduce a thickness of the OPL to a boundary defined by the predetermined depth of the dissolving factor.

### BACKGROUND

### Technical Field

The present invention relates generally to planarization techniques in semiconductor device manufacturing, and more specifically to the field of photolithography patterning for determining the planarization overburden depth by triggering it by a process interaction.

### Description of the Related Art

In a semiconductor process, in order to secure depth of focus (DOF) of lithography, it is desired that the surface of a to-be-processed object has high flatness. Although there is a chemical mechanical polishing (CMP) technology as a processing technology for planarization, polishing damage (e.g., scratches) caused by abrasive grains (e.g., physical polishing agent) in a slurry to be used provides a cause for yield reduction.

### SUMMARY

In accordance with an embodiment, a planarization method for maintaining a substantially planar surface is provided. The method includes forming an organic planarization layer (OPL) over active devices, where the OPL has a chemical affinity in a to-be-incorporated dissolving factor, incorporating the dissolving factor, and triggering the dissolving factor with an enabler to reduce a thickness of the OPL to a boundary defined by the predetermined depth of the dissolving factor.

In accordance with another embodiment, a planarization method for maintaining a substantially planar surface is provided. The method includes forming an organic planarization layer (OPL) over active devices, incorporating a dissolving factor (e.g., nitrogen) to a predetermined depth within the OPL by way of, e.g., plasma, implant, deposition, etc., thus dissolving the OPL to reduce a thickness of the OPL by way of, e.g., wet chemistry to a boundary defined by the predetermined depth of the nitride dissolving factor.

In accordance with yet another embodiment, a method for controlling a height of a planarization layer formed over active devices is provided. The method includes incorporating a nitride dissolving factor to a predetermined depth within the planarization layer and triggering the nitride dissolving factor with plasma to reduce a thickness of the planarization layer to a boundary defined by the predetermined depth of the nitride dissolving factor.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1 is a cross-sectional view of a semiconductor structure including an organic planarization layer (OPL) formed over active devices, in accordance with an embodiment of the present invention;

FIG. 2 is a cross-sectional view of the semiconductor structure of FIG. 1 where the dissolving factor is incorporated or embedded within the OPL, in accordance with an embodiment of the present invention;

FIG. 3 is a cross-sectional view of the semiconductor structure of FIG. 2 where the dissolving factor included in the OPL is removed by a triggering process, in accordance with an embodiment of the present invention;

FIG. 4 illustrates unexpected results of an example OPL including a dissolving factor therein, in accordance with an embodiment of the present invention;

FIG. 5 illustrates a method for planarization which involves a dissolving factor, in accordance with an embodiment of the present invention; and

FIG. 6 is a lithography tool for depth of focus and surface topology, in accordance with an embodiment of the present invention.

Throughout the drawings, same or similar reference numerals represent the same or similar elements.

### DETAILED DESCRIPTION

Embodiments in accordance with the present invention provide methods and devices for implementing a planarization technique in semiconductor lithography for accurately patterning on a flat surface.

The effect of focus on a projection lithography system (such as a stepper or a scanner) is an important part of understanding and controlling a lithographic process. As feature sizes decrease, their sensitivity to focus errors increases. Focus sensitivity can be a limitation of the use of optical lithography for smaller and smaller features and has altered the nature of modern optical lithography (e.g., the use of chemical mechanical polishing (CMP) to reduce focus errors). In general, depth of focus (DOF) can be thought of as the range of focus errors that a process can tolerate and still give acceptable lithographic results. A change in focus results in two major changes to the final lithographic result, that is, the photoresist profile changes and the sensitivity of the process to other processing errors is changed. The first of these effects, the photoresist profile change, is the most obvious and the most easily observed consequence of defocus. Usually, photoresist profiles are described by using three parameters: the linewidth (also called the critical dimension, CD), the sidewall angle, and the resist thickness of the feature (which is useful for lines or islands, but not spaces or contacts). The variation of linewidth, sidewall angle, or resist loss with focus can be readily determined for any given set of conditions. Thus, DOF can be defined as the range of focus which keeps the resist profile of a given feature within all specifications (linewidth, sidewall angle, and resist loss) over a specified exposure range.

The exemplary embodiments of the present invention employ a solution for accurately controlling a planarization depth without damaging the active devices. The planarization technique includes employing a dissolving factor that is embedded or incorporated within a substrate, such as an organic planarization layer. The dissolving factor can penetrate the organic planarization layer to a predetermined or controlled depth. The depth can be controlled, e.g., by plasma or implant techniques. Thus, the depth of the dissolving factor within the organic planarization layer can dictate or designate a boundary or border at which a triggering process maintains remaining organic planarization layer (OPL) over the active devices.

The exemplary embodiments of the present invention employ a solution for accurately controlling a planarization depth without damaging the active devices by employing a triggering process that can remove the dissolving factor such that a thin layer of OPL remains above the active devices (e.g., fins) without creating any damage to the active devices. In fact, the dissolving factor can be controlled to stop or terminate at a safe distance or predetermined distance from the active devices. Thus, a designer can use plasma or implant tools to deposit the dissolving factor within the OPL at a desired or suitable distance. The triggering process then removes all the dissolving factor to its defined depth, and, thus, the dissolving factor can dictate or designate a safe boundary or border between the top surface of the remaining OPL and the active devices underneath.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this invention.

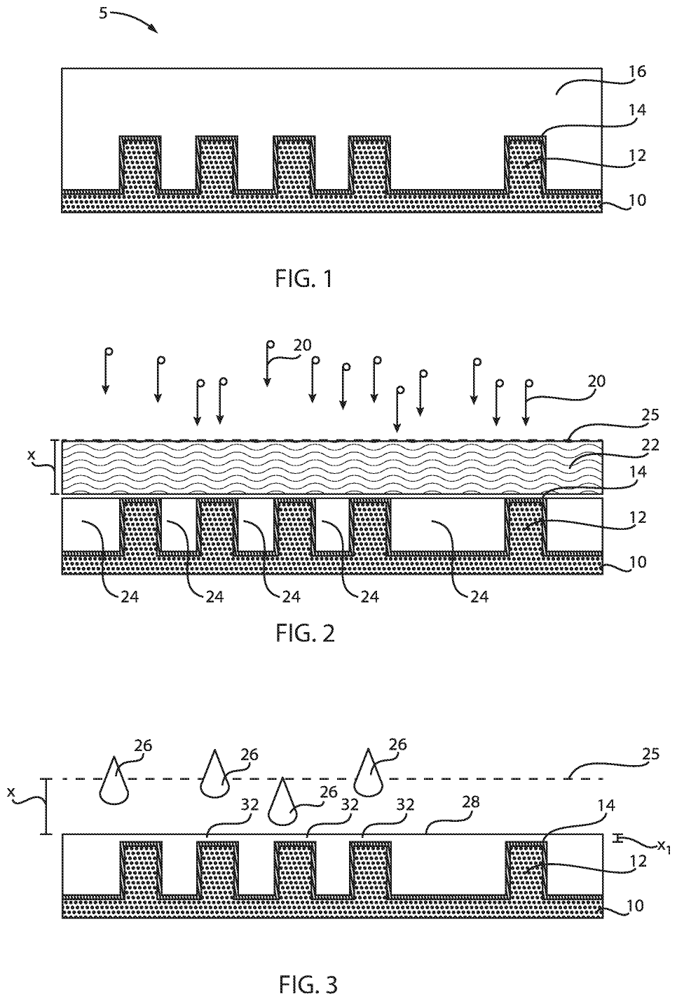

FIG. 1 is a cross-sectional view of a semiconductor structure including an organic planarization layer (OPL) formed over active devices, in accordance with an embodiment of the present invention.

In various exemplary embodiments, a semiconductor structure 5 includes fins 12 formed over a substrate 10. Optionally, a dielectric liner 14 can be formed over the fins 12 and portions of the substrate 10. The dielectric liner 14 can extend over all the fins 12. An organic planarization layer 16 can be formed over the fins 12.

The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, Al₂O₃, SiO₂, GaAs, SiC, or SiGe. The substrate 10 can also have multiple material layers. In some embodiments, the substrate 10 includes a semiconductor material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V (e.g., GaAs, AlGaAs, InAs, InP, etc.), II-V compound semiconductor (e.g., ZnSe, ZnTe, ZnCdSe, etc.) or other like semiconductor. In addition, multiple layers of the semiconductor materials can be used as the semiconductor material of the substrate 10. In some embodiments, the substrate 10 includes both semiconductor materials and dielectric materials.

The plurality of fins 12 are formed from a semiconductor material including, but not limited to Si, strained Si, SiC, SiGe, SiGeC, Si alloys, Ge, Ge alloys, GaAs, InAs, InP, as well as other III/V and II/VI compound semiconductors. The plurality of fins 12 can be etched by employing, e.g., a reactive ion etch (RIE) or the like. In other embodiments, the etching can include a dry etching process such as, for example, reactive ion etching, plasma etching, ion etching or laser ablation. The etching can further include a wet chemical etching process in which one or more chemical etchants are employed to remove portions of the layers.

The plurality of fins 12 can be, e.g., silicon (Si) fins. In another exemplary embodiment, the plurality of fins 12 can be, e.g., silicon germanium (SiGe) fins. Yet in another exemplary embodiment, some of fins 12 can be a material that is different from the other fins. For example, some fins can be silicon fins while others can be silicon germanium (SiGe) fins. One skilled in the art can contemplate forming fins 12 from any type of materials.

Liner 14 is shown formed over the plurality of fins 12. The liner 14 can be formed by first providing a spacer material and then etching the spacer material. The spacer material can include any dielectric spacer material including, for example, a dielectric oxide, dielectric nitride, and/or dielectric oxynitride. In one example, the spacer material can include silicon oxide or silicon nitride (SiN). The spacer material can be provided by a deposition process including, for example, chemical vapor deposition (CVD), plasma enhanced chemical vapor deposition (PECVD), or physical vapor deposition (PVD). In some embodiments, the liner 14 can have a thickness within the range of about 2-10 nm.

The OPL layer 16 can be employed as a lithographic stack to pattern the underlying layers. The OPL layer 16 is formed at a predetermined thickness to provide reflectivity and topography control during etching of the layers below. The OPL layer 16 can include an organic material, such as a polymer. The thickness of the OPL 16 can be in a range from about 60 nm to about 600 nm.

In lithography for micromachining, the photosensitive material used is usually a photoresist (also called resist, other photosensitive polymers are also used). When resist is exposed to a radiation source of a specific wavelength, the chemical resistance of the resist to developer solution changes. If the resist is placed in a developer solution after selective exposure to a light source, it will etch away one of the two regions (exposed or unexposed). If the exposed material is etched away by the developer and the unexposed region is resilient, the material is considered to be a positive resist. If the exposed material is resilient to the developer and the unexposed region is etched away, it is considered to be a negative resist.

A photoresist is a light-sensitive material used in processes, such as photolithography. The process begins by coating a substrate with a light-sensitive organic material. A patterned mask is then applied to the surface to block light, so that only unmasked regions of the material will be exposed to light. A solvent, called a developer, is then applied to the surface. In the case of a positive photoresist, the photo-sensitive material is degraded by light and the developer will dissolve away the regions that were exposed to light, leaving behind a coating where the mask was placed. In the case of a negative photoresist, the photosensitive material is strengthened (either polymerized or cross-linked) by light, and the developer will dissolve away only the regions that were not exposed to light, leaving behind a coating in areas where the mask was not placed.

A positive resist is a type of photoresist in which the portion of the photoresist that is exposed to light becomes soluble to the photoresist developer. The unexposed portion of the photoresist remains insoluble to the photoresist developer.

A negative photoresist is a type of photoresist in which the portion of the photoresist that is exposed to light becomes insoluble to the photoresist developer. The unexposed portion of the photoresist is dissolved by the photoresist developer.

Thus, there are two types of photoresist used in photolithography: positive resist and negative resist. A positive resist is initially insoluble in the developer solution. After exposure, the exposed region of the resist becomes soluble in the developer solution and is then selectively removed by the developer solution during the subsequent development step. The unexposed region of the positive resist remains on the substrate to form a pattern in the photoresist layer. The selective removal of the exposed region of a photoresist is thus called “positive development.”

A negative resist behaves in the opposite manner. The negative resist is initially soluble in the developer solution. Exposure to radiation usually initiates a crosslinking reaction which causes the exposed region of the negative resist to become insoluble in the developer solution. During the subsequent development step, the unexposed region of the negative resist is selectively removed by the developer solution, leaving the exposed region on the substrate to form a pattern. Contrary to the “positive development,” a “negative development” refers to a process that selectively removes the unexposed region of a photoresist.

FIG. 2 is a cross-sectional view of the semiconductor structure of FIG. 1 where the dissolving factor is incorporated or embedded within the OPL, in accordance with an embodiment of the present invention.

In various example embodiments, a dissolving factor 22 is incorporated or embedded within the OPL 16 by techniques 20. The OPL layer 16 can thus include a dissolving factor 22 therein. The dissolving factor 22 can extend a distance “X” within the OPL 16. The dissolving factor 22 penetrates through a top surface 25 of the OPL 16. The dissolving factor 22 does not contact the dielectric liner 14. The dissolving factor 22 is kept a safe distance “X1” away from the actual devices (e.g., fins 12). Thus, there is avoidance of interaction between the dissolving factor 22 and device electrical behavior. The safe distance “X1” can be established based on the techniques 20 employed to incorporate or embed the dissolving factor 22 within the OPL 16. Stated differently, the dissolving factor 22 does not enter into regions 24 between the fins 12 or small regions directly above dielectric liner 14. However, in an alternative embodiment, it is envisioned that the dissolving factor 22 extends below a top surface of the fins 12.

The depth the dissolving factor 22 can reach within the OPL 16 can be tightly and accurately controlled by plasma or implant techniques or any other diffusion apparatus 20. The dissolving factor 22 can penetrate and dissolve within the OPL 16 to a depth of, e.g., about 60 nm. This depth could be set by the OPL material (e.g., how dense or easy it is to defuse within the OPL 16). This depth could be also set by ion implantation (e.g., how deep a designer desires to implant within the OPL 16). The depth can be more than, e.g., 60 nm deep into the OPL 16 in one example embodiment.

In one example, the dissolving factor 22 is a nitride. In other example embodiments, the dissolving factor 22 can be carbon or oxygen.

In one example, the enabler can be plasma. In other example embodiments, the enabler can be ion implantation coating deposition with diffusion by anneal. Ion implantation is a low-temperature process by which ions of one element are accelerated into a solid target, thereby changing the physical, chemical, or electrical properties of the target. The ions can alter the elemental composition of the target when they stop and remain in the target. In the instant case, the target is the OPL 16. One skilled in the art can contemplate a plurality of different dissolving factor/enabler combinations.

FIG. 3 is a cross-sectional view of the semiconductor structure of FIG. 2 where the dissolving factor included in the OPL is removed by a triggering process, in accordance with an embodiment of the present invention.

In various example embodiments, the OPL 16 incorporating the dissolving factor 22 can be etched. The etching 26 of the OPL 16 can be performed using known techniques and dry etching or wet etching chemistries suitable for the materials used to form the OPL 16. The etching can be triggered by an enabler 20, 22. The enabler 20, 22 can be incorporated by plasma, implant, light exposure, etc.

In one example, the etching is an isotropic wet etch. The wet etching process can be performed by using diluted hydrofluoric acid (HF) or hydrogen peroxide (H₂O₂) or diluted ammonia (NH₃OH) and an H₂0₂ mixture. The etchants used in this wet etching process can include an oxidizing agent, such as, for example, hydrogen peroxide, which can oxidize metal structures, such as a metal hard mask (not shown), thereby facilitating its removal.

Non-limiting examples of wet etch processes that can be used to form the recess include hydrogen peroxide (H₂O₂), potassium hydroxide (KOH), ammonium hydroxide (ammonia), tetramethylammonium hydroxide (TMAH), hydrazine, or ethylene diamine pyrocatechol (EDP), or any combination thereof.

The OPL 16 can be reduced a certain distance based on how deep the dissolving factor 22 reaches within the OPL 16. In one example, the entirety of the dissolving factor 22 is removed by the etch 26. Thus, the dissolving factor 22 can determine or dictate or designate how far down the OPL 16 is reduced or etched or removed. In other words, there can be a direct correlation between the depth of the dissolving factor 22 and the remaining OPL thickness. Stated differently, the dissolving factor 22 designates an upper boundary or border of the remaining OPL. Thus, a thickness of the remaining OPL can be controlled so that it is maintained a safe distance “X1” above active devices (e.g., fins 12). A top surface 28 of the remaining OPL is illustrated.

Therefore, in one example, a designer may desire a thickness of at least 20 nm above the active devices (e.g., to protect such active devices). If the OPL 16 has a thickness of about 100 nm, then the dissolving factor 22 can be incorporated within the OPL 16 to a controlled distance of about 80 nm. When etching is performed, the top 80 nm of OPL 16 including the dissolving factor 16 are removed, and a 20 nm OPL remains above the active devices in accordance with the designer's desired specifications. In one example, the remaining OPL can be less than half the original OPL 16.

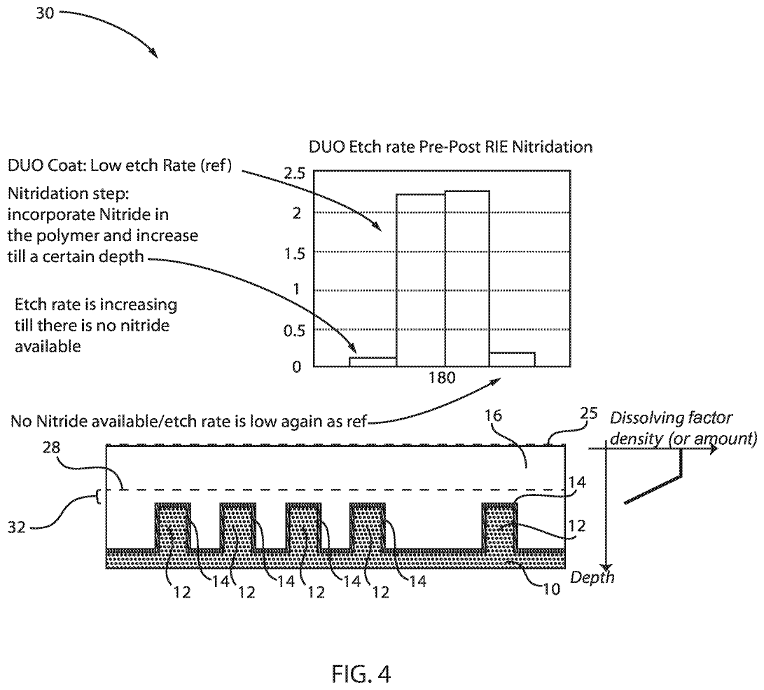

FIG. 4 illustrates a graph 30 with unexpected results of an example OPL including a dissolving factor, in accordance with an embodiment of the present invention.

In various example embodiments, the incorporation of a dissolving factor 22 within the OPL 16 provides the unexpected results of maintaining a certain level of controlled OPL directly above the active devices, without penetrating the active devices. For example, if the dissolving factor 22 is a nitride and the enabler is plasma, a certain level 32 of OPL 16 remains over the active devices. The etch does not extend to the liner 14. In fact, the OPL level 32 remains a safe distance above the dielectric liner 14 to avoid damaging any active devices. The final top surface 28 is substantially planar or flat. Substantially planar or flat can include a 2 nm or less margin of error. In other words, the top surface 28 can be flat within a 2 nm range.

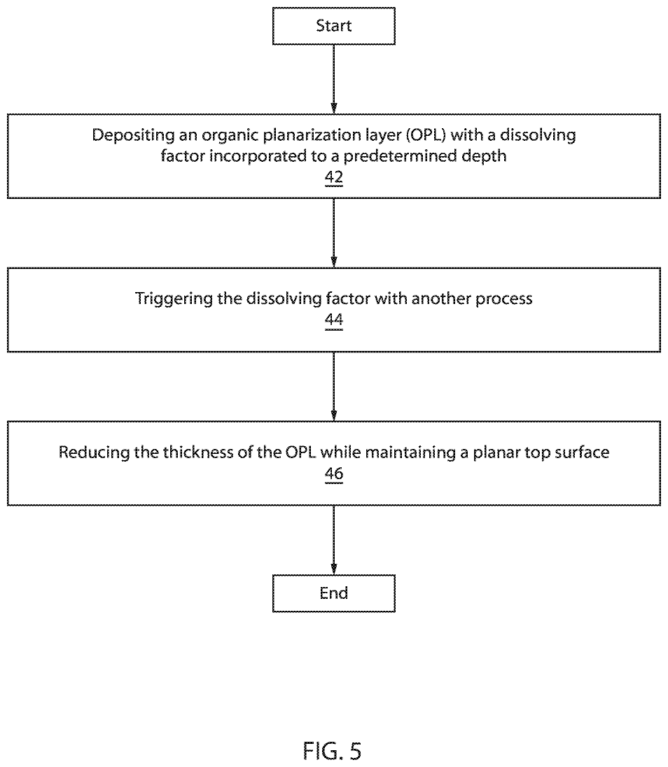

FIG. 5 illustrates a method for planarization which involves a dissolving factor, in accordance with an embodiment of the present invention.

At block 42, an organic planarization layer (OPL) with a dissolving factor formed therein is deposited over a substrate to a predetermined depth. The dissolving factor can be a nitride.

At block 44, the dissolving factor is triggered by another process. The triggering process or enabler can be plasma or ion implantation.

At block 46, the thickness of the OPL is reduced while maintaining a planar top surface. The top planar surface is a safe distance away from the active devices directly underneath the OPL.

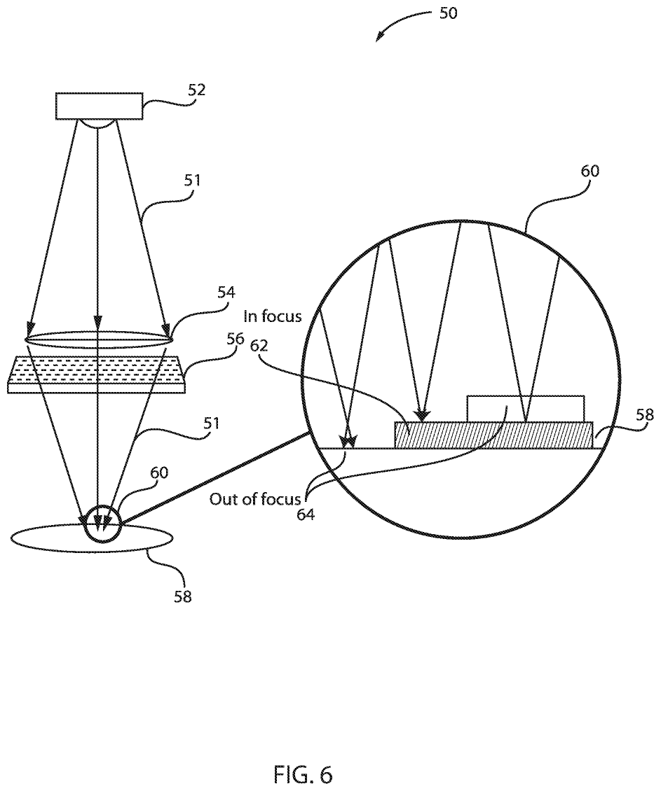

FIG. 6 is a lithography tool for depth of focus and surface topology, in accordance with an embodiment of the present invention.

Usually lithography is performed as part of a well-characterized module, which includes the wafer surface preparation, photoresist deposition, alignment of the mask and wafer, exposure, develop and appropriate resist conditioning. The lithography process steps need to be characterized as a sequence in order to ensure that the remaining resist at the end of the modules is an optimal image of the mask, and has the desired sidewall profile.

The standard steps found in a lithography module are (in sequence): dehydration bake, HMDS prime, resist spin/spray, soft bake, alignment, exposure, post exposure bake, develop hard bake and de-scum. Not all lithography modules will include all the process steps. A brief explanation of the process steps is included for completeness. HMDS is an organosilicon compound with the molecular formula [(CH₃)₃Si]₂NH.

The dehydration bake involves dehydrating the wafer to aid resist adhesion.

The HMDS prime involves coating of the wafer surface with an adhesion promoter, and not necessarily for all surfaces.

The resist spin/spray involves coating of the wafer with resist either by spinning or spraying. A uniform coat is desired.

The soft bake step involves driving off some of the solvent in the resist, which can result in a significant loss of mass of resist and thickness. This process makes the resist more viscous.

The alignment step involves aligning the pattern on the mask to features on the wafers.

The exposure step involves projection of the mask image on the resist to cause selective chemical property changes.

The post exposure bake step involves baking of the resist to drive off further solvent content. This process makes the resist more resistant to etchants (other than the developer).

The develop step involves selective removal of the resist after exposure (exposed resist if resist is positive, unexposed resist if resist is negative). This step usually involves a wet process.

The hard bake step involves driving off most of the remaining solvent from the resist.

The de-scum step involves removal of a thin layer of resist scum that can occlude open regions in pattern and helps open up corners.

Regarding photolithography, a few assumptions can be made. Firstly, it is assumed that a well characterized module exists that prepares the wafer surface, deposits the requisite resist thickness, aligns the mask perfectly, exposes the wafer with the optimal dosage, develops the resist under the optimal conditions, and bakes the resist for the appropriate times at the appropriate locations in the sequence. Unfortunately, even if the module is executed perfectly, the properties of lithography are very feature and topography dependent.

The designer influences the lithographic process through his/her selections of materials, topography and geometry. The material(s) upon which the resist is to be deposited is important, as it affects the resist adhesion. The reflectivity and roughness of the layer beneath the photoresist determines the amount of reflected and dispersed light present during exposure. It is difficult to obtain a nice uniform resist coat across a surface with high topography, which complicates exposure and development as the resist has different thickness in different locations. If the surface of the wafer has many different height features, the limited depth of focus of most lithographic exposure tools will become an issue (FIG. 4). FIG. 4 depicts a lithography tool 50 that includes light source 52 that emits light 51 onto reduction optics 54. The light 51 travels through the optics 54 and through a mask 56. The light 51 travels through the mask 56 and onto a wafer 58. An enlarged view 60 illustrates in-focus regions 62 and out-of-focus regions 64.

The exemplary embodiments of the present invention solve such depth of focus issues by incorporating or embedding or providing a dissolving factor 22 within an OPL 16. The depth of the dissolving factor 22 within the OPL 16 can be tightly and accurately controlled by, e.g., plasma or implant techniques. A triggering process can remove the dissolving factor 22 such that a thin layer of OPL remains above the active devices (e.g., fins 12) without creating any damage to the active devices. In fact, the dissolving factor 22 can be controlled to stop or terminate at a safe distance from the active devices. Thus, a designer can use plasma or implant tools to deposit the dissolving factor 22 within the OPL 16 at a desired or suitable distance. The triggering process then removes all the dissolving factor 22, and, thus, the dissolving factor can dictate a safe boundary or border between the top surface of the remaining OPL and the active devices underneath.

In various embodiments, it is contemplated that the etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist. The patterned photoresist can be removed utilizing an ashing process.

In various embodiments, the materials and layers can be deposited by physical vapor deposition (PVD), chemical vapor deposition (CVD), atomic layer deposition (ALD), molecular beam epitaxy (MBE), or any of the various modifications thereof, for example plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In various embodiments, formation of a layer can be by one or more deposition processes, where, for example, a conformal layer can be formed by a first process (e.g., ALD, PE-ALD, etc.) and a fill can be formed by a second process (e.g., CVD, electrodeposition, PVD, etc.).

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a structure and method for controlling a depth or height of a planarization layer over active devices (which are intended to be illustrative and not limiting), it is noted that modifications and variations can be made by persons skilled in the art in light of the above teachings. It is therefore to be understood that changes can be made in the particular embodiments described which are within the scope of the invention as outlined by the appended claims. Having thus described aspects of the invention, with the details and particularity required by the patent laws, what is claimed and desired protected by Letters Patent is set forth in the appended claims.

What is claimed is:

1. A planarization method for maintaining a substantially planar surface, the method comprising:
forming an organic planarization layer (OPL) over active devices;
incorporating a dissolving factor to a predetermined depth within the OPL; and
triggering the dissolving factor with an enabler to reduce a thickness of the OPL to a boundary defined by the predetermined depth of the dissolving factor.

2. The method of claim 1, wherein the active devices are a plurality of fins.

3. The method of claim 2, wherein the dissolving factor includes a nitride.

4. The method of claim 3, wherein the enabler includes plasma.

5. The method of claim 3, wherein the enabler includes an implant technique.

6. The method of claim 1, wherein an entirety of the dissolving factor incorporated within the OPL is removed.

7. The method of claim 6, wherein a remaining OPL remains over the active devices.

8. The method of claim 7, wherein the remaining OPL is less than half the initial OPL.

9. A planarization method for maintaining a substantially planar surface, the method comprising:
forming an organic planarization layer (OPL) over active devices;
incorporating a nitride dissolving factor to a predetermined depth within the OPL; and
triggering the nitride dissolving factor with plasma to reduce a thickness of the OPL to a boundary defined by the predetermined depth of the nitride dissolving factor.

10. The method of claim 9, wherein the active devices are a plurality of fins.

11. The method of claim 9, wherein an entirety of the nitride dissolving factor incorporated within the OPL is removed.

12. The method of claim 11, wherein a remaining OPL remains over the active devices.

13. The method of claim 12, wherein the remaining OPL is less than half the initial OPL.

14. The method of claim 13, wherein the initial OPL has a thickness of about 60 nm to about 600 nm.

15. The method of claim 9, wherein the nitride dissolving factor incorporated into the OPL prevents damage to the active devices from the plasma.

16. A method for controlling a height of a planarization layer formed over active devices, the method comprising:
incorporating a nitride dissolving factor to a predetermined depth within the planarization layer; and
triggering the nitride dissolving factor with plasma to reduce a thickness of the planarization layer to a boundary defined by the predetermined depth of the nitride dissolving factor.

17. The method of claim 16, wherein the planarization layer is an organic planarization layer.

18. The method of claim 16, wherein the active devices are a plurality of fins.

19. The method of claim 16, wherein an entirety of the nitride dissolving factor incorporated within the OPL is removed.

20. The method of claim 16, wherein a remaining OPL remains over the active devices.
